(19) United States
(12) Patent Application Publication
(10) Pub. No.: US 2025/0338608 A1
(43) Pub. Date: Oct. 30, 2025

(54) SEMICONDUCTOR INTEGRATED CIRCUIT DEVICE

(71) Applicant: Socionext Inc., Kanagawa (JP)

(72) Inventor: Masachika ONO, Yokohama-shi (JP)

(21) Appl. No.: 19/251,322

(22) Filed: Jun. 26, 2025

Related U.S. Application Data
(63) Continuation of application No. PCT/JP2024/003896, filed on Feb. 6, 2024.

(30) Foreign Application Priority Data
Feb. 8, 2023 (JP) 2023-017560

(51) Int. Cl. H10D 84/83; H01L 23/528; H03K 19/017; H10D 30/00; H10D 30/43; H10D 62/10

(52) U.S. Cl. CPC H10D 84/8311; H01L 23/528; H01L 23/5283; H03K 19/017; H10D 30/43; H10D 30/502; H10D 62/121; H10D 84/832

(57) ABSTRACT

A layout structure of a standard cell lying astride standard cell rows different in height is provided. A double-height cell is formed astride first and second cell rows. The height of the second cell is greater than the height of the first cell. The double-height cell includes a first logic circuit that receives an input signal and outputs a signal to an internal node and a second logic circuit that receives the signal from the internal node and outputs an output signal. Transistors constituting the first logic circuit are formed in a region of the first cell row, and transistors constituting the second logic circuit are formed in a region of the second cell row.

### CROSS-REFERENCE TO RELATED APPLICATIONS

This is a continuation of International Application No. PCT/JP2024/003896 filed on Feb. 6, 2024, which claims priority to Japanese Patent Application No. 2023-017560 filed on Feb. 8, 2023. The entire disclosures of these applications are incorporated by reference herein.

### BACKGROUND

The present disclosure relates to a semiconductor integrated circuit device.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, whereby an LSI chip is designed.

Also, as for a transistor, which is a basic constituent of an LSI, improvement in integration degree, reduction in operating voltage, and improvement in operating speed have been achieved by reducing (scaling) the gate length. In recent years, however, increase in off current due to excessive scaling and the resulting significant increase in power consumption have raised a problem. To solve this problem, three-dimensional transistors, of which the transistor structure has changed from the conventional planar structure to a three-dimensional structure, have been vigorously studied. A nanosheet FET is one example of such three-dimensional transistors.

US Patent Application Publication No. 2022/0262786 (Patent Document 1) discloses a semiconductor integrated circuit device in which standard cell rows different in height are arranged alternately and some standard cells lie astride a plurality of standard cell rows.

US Patent Application Publication No. 2021/375853 (Patent Document 2) discloses, for further higher integration, a technique of providing interconnects on the back of a substrate right under transistors and connecting the sources/drains of the transistors to the interconnects.

Patent Document 1 describes optimizing the performance of standard cells lying astride a plurality of standard cell rows different in height. However, the cited patent document has not disclosed a specific layout structure of such standard cells.

An objective of the present disclosure is presenting a layout structure of a standard cell lying astride a plurality of standard cell rows different in height.

### SUMMARY

According to the first mode of the disclosure, a semiconductor integrated circuit device includes: a first cell row including a plurality of standard cells arranged in a first direction; a second cell row including a plurality of standard cells arranged in the first direction and adjoining the first cell row in a second direction perpendicular to the first direction; and a double-height cell placed astride the first cell row and the second cell row and having a height greater than the height of the plurality of standard cells included in the first and second cell rows, wherein the height of the second cell row is greater than the height of the first cell row, the double-height cell includes a first logic circuit configured to receive an input signal from an input terminal and output a signal to an internal node, and a second logic circuit configured to receive the signal from the internal node and output an output signal to an output terminal, a first transistor constituting the first logic circuit is formed in a region included in the first cell row, and a second transistor constituting the second logic circuit is formed in a region included in the second cell row.

According to the above mode, the double-height cell is placed astride the first cell row and the second cell row. The height of the second cell row is greater than the height of the first cell row. The double-height cell includes a first logic circuit that receives an input signal and outputs a signal to an internal node and a second logic circuit that receives the signal from the internal node and outputs an output signal. First transistors constituting the first logic circuit are formed in a region included in the first cell row, and second transistors constituting the second logic circuit are formed in a region included in the second cell row. Therefore, the channel width of the second transistors can be made greater than the channel width of the first transistors. In this way, a circuit small in input capacity and high in output drive capability can be implemented with a small area.

According to the second mode of the disclosure, a semiconductor integrated circuit device includes: a first cell row including a plurality of standard cells arranged in a first direction; a second cell row including a plurality of standard cells arranged in the first direction and adjoining the first cell row in a second direction perpendicular to the first direction; and a double-height cell placed astride the first cell row and the second cell row and having a height greater than the height of the plurality of standard cells included in the first and second cell rows, wherein the height of the second cell row is greater than the height of the first cell row, the double-height cell includes a first logic circuit configured to receive an input signal from an input terminal and output a signal to an internal node, and a second logic circuit configured to receive the signal from the internal node and output an output signal to an output terminal, a first transistor constituting the first logic circuit is formed in a region included in the second cell row, and a second transistor constituting the second logic circuit is formed in a region included in the first cell row.

According to the above mode, the double-height cell is placed astride the first cell row and the second cell row. The height of the second cell row is greater than the height of the first cell row. The double-height cell includes a first logic circuit that receives an input signal and outputs a signal to an internal node and a second logic circuit that receives the signal from the internal node and outputs an output signal. First transistors constituting the first logic circuit are formed in a region included in the second cell row, and second transistors constituting the second logic circuit are formed in a region included in the first cell row. Therefore, the channel width of the second transistors can be made smaller than the channel width of the first transistors. Thus, since the output drive capability of the first logic circuit is great and the input capacity of the second logic circuit is small, the delay inside the standard cell can be reduced.

According to the present disclosure, a small-area, high-speed semiconductor integrated circuit device can be implemented using a standard cell lying astride a plurality of standard cell rows different in height.

### BRIEF DESCRIPTION OF THE DRAWINGS

FIG. 1 shows an example of a block layout of a semiconductor integrated circuit device according to an embodiment.

FIGS. 2A and 2B are plan views showing layout structure examples of single-height cells.

FIG. 3 is a circuit diagram of a buffer circuit.

FIG. 4 is a plan view showing a layout structure example of a double-height cell according to the first embodiment.

FIGS. 5A and 5B are cross-sectional views of the layout structure of FIG. 4.

FIG. 6 is a plan view showing a layout structure example of a double-height cell according to the first embodiment.

FIGS. 7A and 7B show another configuration example.

FIG. 8 is a plan view showing a layout structure example of a double-height cell according to the first embodiment.

FIG. 9 is a circuit diagram of a 2-input AND circuit.

FIG. 10 is a plan view showing a layout structure example of a double-height cell according to the first embodiment.

FIG. 11 is a circuit diagram of a 2-input OR circuit.

FIG. 12 is a plan view showing a layout structure example of a double-height cell according to the first embodiment.

FIG. 13 is a circuit diagram of a 4-input AND circuit.

FIG. 14 is a plan view showing a layout structure example of a double-height cell according to the first embodiment.

FIG. 15 is a plan view showing a layout structure example of a double-height cell according to the second embodiment.

FIG. 16 is a plan view showing a layout structure example of a double-height cell according to the second embodiment.

FIG. 17 is a plan view showing a layout structure example of a double-height cell according to the second embodiment.

### DETAILED DESCRIPTION

Embodiments of the present disclosure will be described hereinafter with reference to the accompanying drawings. In the following embodiments, it is assumed that the semiconductor integrated circuit device includes a plurality of standard cells (hereinafter simply called cells as appropriate), and at least some of the standard cells include nanosheet field effect transistors (FETs). The nanosheet FET is a FET using a thin sheet (nanosheet) through which a current flows. Such a nanosheet is formed of silicon, for example. Note that, in the present disclosure, the transistors included in the standard cells are not limited to nanosheet FETs.

As used herein, “VDD” and “VSS” refer to the power supply voltages or the power supplies themselves. Also, as used herein, an expression indicating that sizes such as widths are identical, like the “same wiring width,” is to be understood as including a range of manufacturing variations. Note that, in the plan views and the cross-sectional views in the following embodiments, illustration of various insulating films may be omitted.

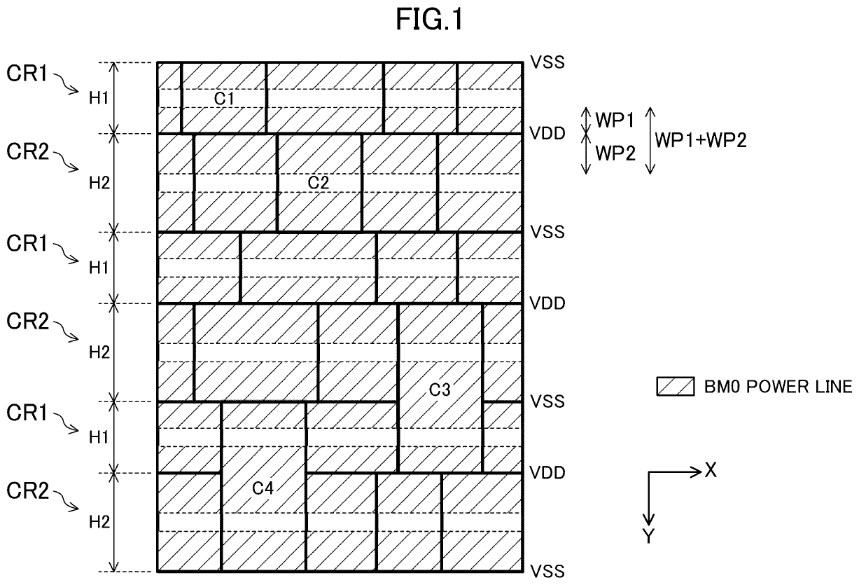

Note that, in the plan views such as FIG. 1, the horizontal direction in the figure is hereinafter referred to as an X direction (corresponding to the first direction), the vertical direction in the figure as a Y direction (corresponding to the second direction), and the direction perpendicular to the substrate plane as a Z direction.

### First Embodiment

FIG. 1 shows an example of a block layout of a semiconductor integrated circuit device according to an embodiment. The block layout of FIG. 1 is configured by placing standard cells. In FIG. 1, only the cell frames of standard cells and power lines are illustrated, omitting illustration of the internal structures of the standard cells and interconnects between the standard cells.

In the block layout of FIG. 1, a plurality of cells arranged in the X direction constitute cell rows CR1 and CR2. The height of the cell rows CR1 is H1, and the height of the cell rows CR2 is H2, where the height H2 is greater than the height H1 (H2>H1). A plurality of cell rows CR1 and CR2 (six rows in FIG. 1) are arranged in the Y direction. The cell rows CR1 and CR2 are placed alternately. Power lines are formed on both ends of the cells in the Y direction, through which power supply potentials VDD and VSS are supplied to the cells from outside. The power lines are formed in a backside metal 0 (BM0) layer that is an interconnect layer provided on the back of a semiconductor chip in which transistors are formed. The width of the power lines in the cell rows CR1 is WP1, and the width of the power lines in the cell rows CR2 is WP2, where the width WP2 is greater than the width WP1 (WP2>WP1). The cell rows CR1 and CR2 are placed in a vertically flipped position every other row so that the power lines between adjacent cell rows can be shared. The width of the power lines shared by the cell rows CR1 and CR2 is (WP1+WP2).

Cells C1 and C2 are single-height cells. The cell C1, placed in the cell row CR1, has the height H1, and the cell C2, placed in the cell row CR2, has the height H2. Cells C3 and C4 are double-height cells. The cells C3 and C4, placed astride the cell rows CR1 and CR2, have a height (H1+H2). In the cell C3, a power line supplying VSS runs across the center portion. In the cell C4, a power line supplying VDD runs across the center portion.

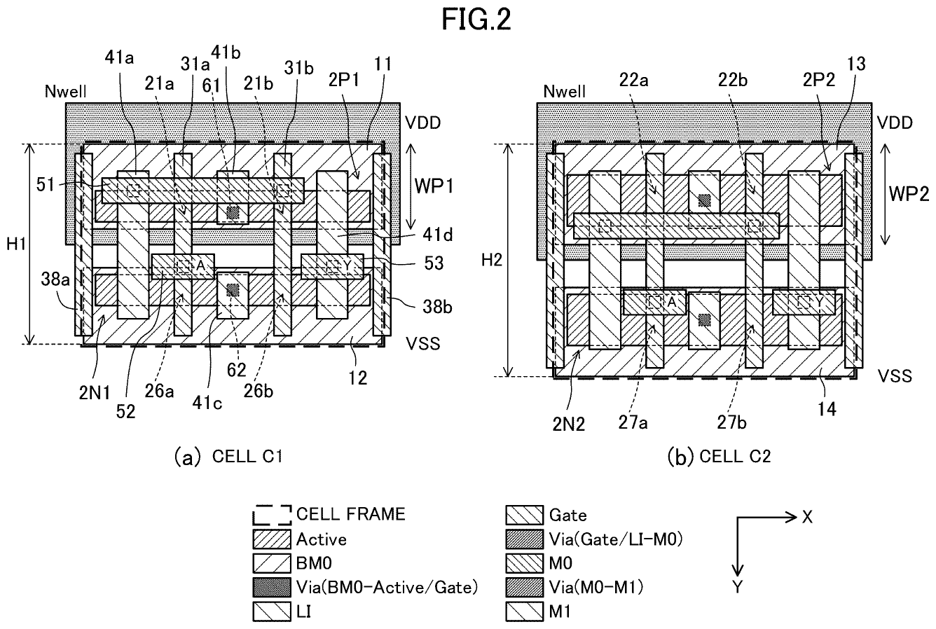

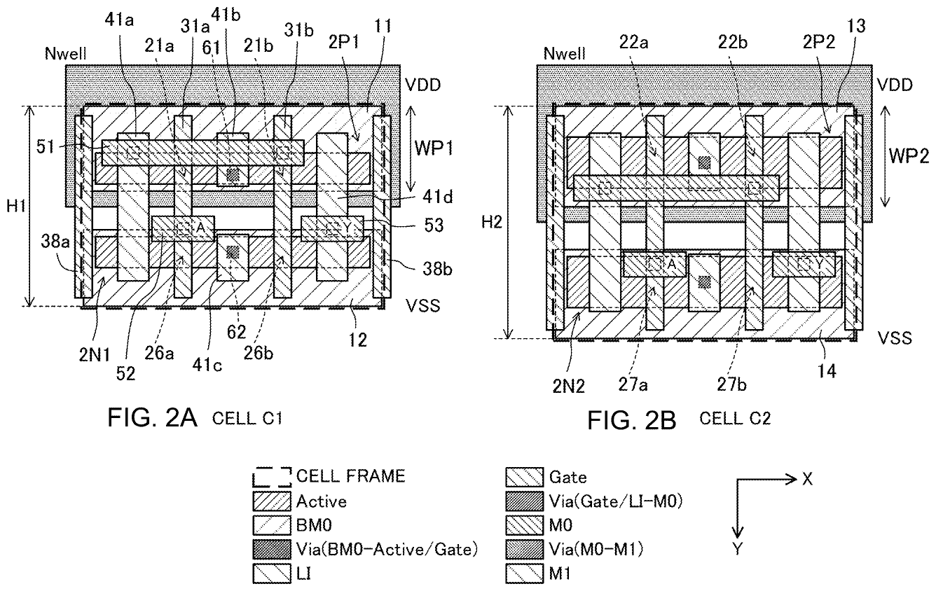

FIGS. 2A-2B are plan views showing layout structure examples of single-height cells in the block layout of FIG. 1, where FIG. 2A shows the cell C1 and FIG. 2B shows the cell C2. Note that, in the block layout of FIG. 1, the cell C1 of FIG. 2A is placed in a vertically flipped position.

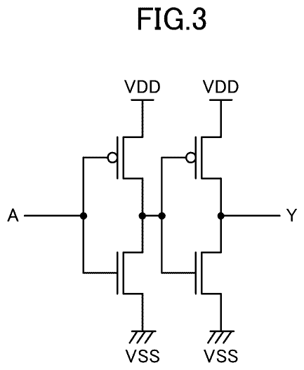

FIG. 3 is a circuit diagram of the single-height cells of FIGS. 2A and 2B. As shown in FIG. 3, the cells C1 and C2 of FIGS. 2A and 2B are each constituted by two-staged inverters, forming a buffer circuit having an input A and an output Y.

As shown in FIG. 2A, in the cell C1, power lines 11 and 12 extending in the X direction are laid on the ends in the Y direction. As shown in FIG. 2B, in the cell C2, power lines 13 and 14 extending in the X direction are laid on the ends in the Y direction. The power lines 11, 12, 13, and 14 are formed in the BM0 layer that is an interconnect layer provided on the back of the semiconductor chip in which transistors are formed. The width of the power lines 11 and 12 is WP1, and the width of the power lines 13 and 14 is WP2. The width WP2 of the power lines 13 and 14 is greater than the width WP1 of the power lines 11 and 12. The power lines 11 and 13 supply the power supply voltage VDD, and the power lines 12 and 14 supply the power supply voltage VSS. The power lines 11 and 12 are shared with other cells in the cell row CR1 including the cell C1, forming power lines extending in the X direction. The power lines 13 and 14 are shared with other cells in the cell row CR2 including the cell C2, forming power lines extending in the X direction. Also, the power lines 11, 12, 13, and 14 are shared between cell rows adjacent in the Y direction.

In the cell C1 shown in FIG. 2A, an active region 2P1 forming the channels, sources, and drains of p-type transistors is formed in a p-type transistor region on an n-type well (NWell). The active region 2P1 overlaps the power line 11 in planar view. The active region 2P1 includes nanosheets 21a and 21b each having a structure of three sheets lying one above another and extending in the X direction, as the channels of the p-type transistors. In the active region 2P1, the portion between the nanosheets 21a and 21b is connected to the power line 11 through a via 61.

An active region 2N1 forming the channels, sources, and drains of n-type transistors is formed in an n-type transistor region on a p-type substrate. The active region 2N1 overlaps the power line 12 in planar view. The active region 2N1 includes nanosheets 26a and 26b each having a structure of three sheets lying one above another and extending in the X direction, as the channels of the n-type transistors. In the active region 2N1, the portion between the nanosheets 26a and 26b is connected to the power line 12 through a via 62.

Note that, in the active regions, the portions that are to be the sources and the drains on both sides of the nanosheets are formed by epitaxial growth from the nanosheets, for example. Note also that the active region of the n-type transistors may be formed on a p-type well, not on the p-type substrate.

Gate interconnects 31a and 31b extending in parallel in the Y direction are formed from the p-type transistor region over to the n-type transistor region. Also, dummy gate interconnects 38a and 38b are formed on the side portions of the cell frame in the X direction. The dummy gate interconnect 38a is shared with a cell placed on the left in the figure, and the dummy gate interconnect 38b is shared with a cell placed on the right in the figure. The gate interconnects 31a and 31b and the dummy gate interconnects 38a and 38b have the same width and are placed at the same pitch.

The gate interconnect 31a surrounds the peripheries of the nanosheets 21a included in the active region 2P1 in the Y and Z directions via gate insulating films (not shown). Also, the gate interconnect 31a surrounds the peripheries of the nanosheets 26a included in the active region 2N1 in the Y and Z directions via gate insulating films (not shown). The gate interconnect 31b surrounds the peripheries of the nanosheets 21b included in the active region 2P1 in the Y and Z directions via gate insulating films (not shown). Also, the gate interconnect 31b surrounds the peripheries of the nanosheets 26b included in the active region 2N1 in the Y and Z directions via gate insulating films (not shown).

Local interconnects 41a, 41b, 41c, and 41d (abbreviated as LI in the figures) extending in the Y direction are formed in a local interconnect layer. The local interconnects 41a and 41d extend from the p-type transistor region over to the n-type transistor region. The local interconnect 41a is connected to the portions that are to be the sources or the drains located on the left side of the gate interconnect 31a in the figure in the active regions 2P1 and 2N1. The local interconnect 41b is connected to the portion that is to be the source or the drain located between the gate interconnects 31a and 31b in the active region 2P1. The local interconnect 41c is connected to the portion that is to be the source or the drain located between the gate interconnects 31a and 31b in the active region 2N1. The local interconnect 41d is connected to the portions that are to be the sources or the drains located on the right side of the gate interconnect 31b in the figure in the active regions 2P1 and 2N1.

Metal interconnects 51, 52, and 53 extending in the X direction are formed in an M0 interconnect layer. The metal interconnect 51 is connected to the local interconnect 41a through a via, and also connected to the gate interconnect 31b through a via. The metal interconnect 52 is connected to the gate interconnect 31a through a via. The metal interconnect 52 corresponds to the input A of the buffer circuit. The metal interconnect 53 is connected to the local interconnect 41d through a via. The metal interconnect 53 corresponds to the output Y of the buffer circuit.

The layout structure of the cell C2 shown in FIG. 2B is basically the same as that of the cell C1 shown in FIG. 2A. However, since the height H2 of the cell C2 is greater than the height H1 of the cell C1 (H2>H1), the size of active regions 2P2 and 2N2 in the Y direction in the cell C2 is greater than the size of the active regions 2P1 and 2N1 in the Y direction in the cell C1. That is, the width of nanosheets 22a and 22b and nanosheets 27a and 27b in the cell C2 is greater than the width of the nanosheets 21a and 21b and the nanosheets 26a and 26b in the cell C1 (note that the width of nanosheets herein refers to the width or the size in the Y direction in the figure). Therefore, the output drive capability of the cell C2 is greater than the output drive capability of the cell C1. Also, the input capacity of the cell C2 is greater than the input capacity of the cell C1.

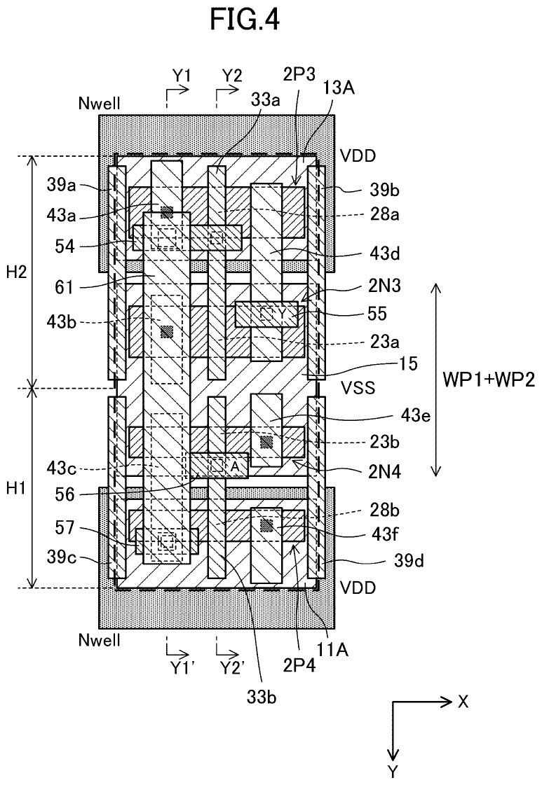

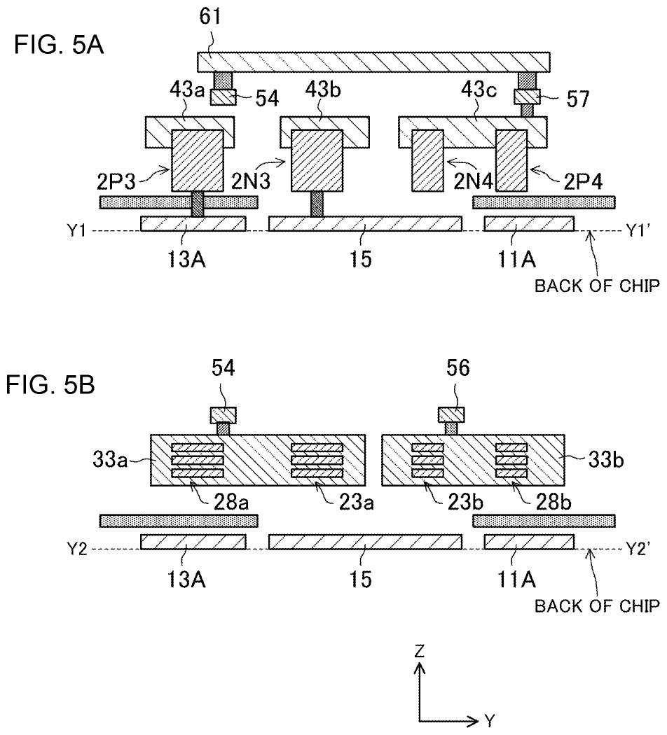

FIG. 4 is a plan view showing a layout structure example of the double-height cell C3 in the block layout of FIG. 1. FIGS. 5A and 5B are cross-sectional views of the layout structure of FIG. 4, where FIG. 5A is a cross section taken along line Y1-Y1′ and FIG. 5B is a cross section taken along line Y2-Y2′. The circuit structure of the cell C3 of FIGS. 4, 5A, and 5B is as shown in FIG. 3, that is, constituted by two-staged inverters, forming a buffer circuit having an input A and an output Y. The input-side inverter corresponds to the first logic circuit according to the present disclosure, and the output-side inverter corresponds to the second logic circuit according to the present disclosure.

As shown in FIG. 4, in the cell C3, a power line 15 supplying VSS is laid in the center portion in the Y direction. The width of the power line 15 is WP1+WP2. Also, in the cell C3, power lines 13A and 11A supplying VDD are placed in the end portions in the Y direction. In the cell C3, in the upper-part region in the figure, which is included in the cell row CR2, having the height H2, transistors constituting the output-side inverter of the buffer circuit are formed. In the lower-part region in the figure, which is included in the cell row CR1, having the height H1, transistors constituting the input-side inverter of the buffer circuit are formed.

In the upper-part region included in the cell row CR2, an active region 2N3 forming the channel, source, and drain of an n-type transistor is formed so as to overlap the power line 15 in planar view. The active region 2N3 includes nanosheets 23a having a structure of three sheets lying one above another and extending in the X direction, as the channel of the n-type transistor. In the active region 2N3, the portion on the left side of the nanosheets 23a is connected to the power line 15 through a via.

In the lower-part region included in the cell row CR1, an active region 2N4 forming the channel, source, and drain of an n-type transistor is formed so as to overlap the power line 15 in planar view. The active region 2N4 includes nanosheets 23b having a structure of three sheets lying one above another and extending in the X direction, as the channel of the n-type transistor. In the active region 2N4, the portion on the right side of the nanosheets 23b is connected to the power line 15 through a via.

An active region 2P3 forming the channel, source, and drain of a p-type transistor is formed so as to overlap the power line 13A placed in the upper end portion in planar view. The active region 2P3 includes nanosheets 28a having a structure of three sheets lying one above another and extending in the X direction, as the channel of the p-type transistor. In the active region 2P3, the portion on the left side of the nanosheets 28a is connected to the power line 13A through a via.

An active region 2P4 forming the channel, source, and drain of a p-type transistor is formed so as to overlap the power line 11A placed in the lower end portion in planar view. The active region 2P4 includes nanosheets 28b having a structure of three sheets lying one above another and extending in the X direction, as the channel of the p-type transistor. In the active region 2P4, the portion on the right side of the nanosheets 28b is connected to the power line 11A through a via.

In the upper-part region included in the cell row CR2, a gate interconnect 33a extending in the Y direction is formed, and dummy gate interconnects 39a and 39b are formed on the side portions of the cell frame in the X direction. The dummy gate interconnect 39a is shared with a cell placed on the left in the figure, and the dummy gate interconnect 39b is shared with a cell placed on the right in the figure. The gate interconnect 33a and the dummy gate interconnects 39a and 39b have the same width and are placed at the same pitch.

The gate interconnect 33a surrounds the peripheries of the nanosheets 28a included in the active region 2P3 in the Y and Z directions via gate insulating films (not shown). Also, the gate interconnect 33a surrounds the peripheries of the nanosheets 23a included in the active region 2N3 in the Y and Z directions via gate insulating films (not shown).

In the lower-part region included in the cell row CR1, a gate interconnect 33b extending in the Y direction is formed, and dummy gate interconnects 39c and 39d are formed on the side portions of the cell frame in the X direction. The dummy gate interconnect 39c is shared with a cell placed on the left in the figure, and the dummy gate interconnect 39d is shared with a cell placed on the right in the figure. The gate interconnect 33b and the dummy gate interconnects 39c and 39d have the same width and are placed at the same pitch.

The gate interconnect 33b surrounds the peripheries of the nanosheets 28b included in the active region 2P4 in the Y and Z directions via gate insulating films (not shown). Also, the gate interconnect 33b surrounds the peripheries of the nanosheets 23b included in the active region 2N4 in the Y and Z directions via gate insulating films (not shown).

Local interconnects 43a, 43b, 43c, 43d, 43e, and 43f extending in the Y direction are formed in a local interconnect layer. The local interconnect 43a is connected to the portion located on the left side of the nanosheets 28a in the figure in the active region 2P3. The local interconnect 43b is connected to the portion located on the left side of the nanosheets 23a in the figure in the active region 2N3. The local interconnect 43c is connected to the portion located on the left side of the nanosheets 23b in the figure in the active regions 2N4 and the portion located on the left side of the nanosheets 28b in the figure in the active regions 2P4.

The local interconnect 43d is connected to the portion located on the right side of the nanosheets 23a in the figure in the active regions 2N3 and the portion located on the right side of the nanosheets 28a in the figure in the active regions 2P3. The local interconnect 43e is connected to the portion located on the right side of the nanosheets 23b in the figure in the active region 2N4. The local interconnect 43f is connected to the portion located on the right side of the nanosheets 28b in the figure in the active region 2P4.

Metal interconnects 54, 55, 56, and 57 extending in the X direction are formed in an MO interconnect layer. The metal interconnect 54 is connected to the gate interconnect 33a through a via. The metal interconnect 55 is connected to the local interconnect 43d through a via, and corresponds to the output terminal Y of the buffer circuit. The metal interconnect 56 is connected to the gate interconnect 33b through a via, and corresponds to the input terminal A of the buffer circuit. The metal interconnect 57 is connected to the local interconnect 43c through a via.

A metal interconnect 61 extending in the Y direction is formed in an M1 interconnect layer that is a metal interconnect layer located above the M0 interconnect layer. The metal interconnect 61 is connected to the metal interconnects 54 and 57 through vias, and corresponds to the inner node of the buffer circuit.

In the double-height cell C3 shown in FIGS. 4, 5A, and 5B, the height H2 of the region included in the cell row CR2 is greater than the height H1 of the region included in the cell row CR1 (H2>H1). Therefore, the size of the active regions 2P3 and 2N3 in the Y direction is greater than the size of the active regions 2P4 and 2N4 in the Y direction. That is, the width of the nanosheets 23a and 28a of the transistors constituting the output-side inverter is greater than the width of the nanosheets 23b and 28b of the transistors constituting the input-side inverter. The cell C3 can therefore implement a buffer circuit small in input capacity (equivalent to that of the cell C1) and high in output drive capability (equivalent to that of the cell C2) with a small area. As a result, a high-speed, small-area semiconductor integrated circuit device can be implemented. This is particularly effective when the output drive capability of a cell connected to the input A of the cell C3 is small and when the load capacity due to a cell or cells and interconnects connected to the output Y is large.

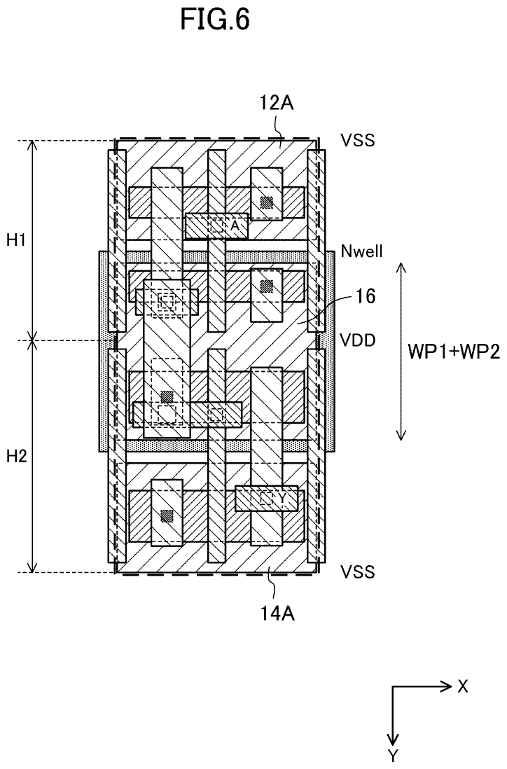

FIG. 6 is a plan view showing a layout structure example of the double-height cell C4 in the block layout of FIG. 1. The circuit structure of the cell C4 of FIG. 6 is as shown in FIG. 3, that is, constituted by two-staged inverters, forming a buffer circuit having an input A and an output Y.

As shown in FIG. 6, in the cell C4, a power line 16 supplying VDD is laid in the center portion in the Y direction. The width of the power line 16 is WP1+WP2. Also, power lines 12A and 14A supplying VSS are laid in the end portions in the Y direction. In the cell C4, in the upper-part region in the figure included in the cell row CR1, having the height H1, transistors constituting the input-side inverter of the buffer circuit are formed. In the lower-part region included in the cell row CR2, having the height H2, transistors constituting the output-side inverter of the buffer circuit are formed.

Since the layout structure of the cell C4 of FIG. 6 can be easily known by analogy from the layout structure of the cell C3 shown in FIGS. 4, 5A, and 5B, detailed description is omitted here.

The double-height cell C4 of FIG. 6 can obtain similar effects to those obtained by the double-height cell C3 shown in FIGS. 4, 5A, and 5B. That is, the height H2 of the lower-part region included in the cell row CR2 is greater than the height H1 of the upper-part region included in the cell row CR1 (H2>H1). Therefore, the width of the nanosheets of the transistors constituting the output-side inverter is greater than the width of the nanosheets of the transistors constituting the input-side inverter. The cell C4 can therefore implement a buffer circuit small in input capacity (equivalent to that of the cell C1) and high in output drive capability (equivalent to that of the cell C2) with a small area. As a result, a high-speed, small-area semiconductor integrated circuit device can be implemented. This is particularly effective when the output drive capability of a cell connected to the input A of the cell C4 is small and when the load capacity due to a cell or cells and interconnects connected to the output Y is large.

While the power lines 11, 11A, 12, 12A, 13, 13A, 14, 14A, 15, and 16 are formed in the interconnect layer provided on the back of the semiconductor chip in the above description, the configuration is not limited to this. According to the present disclosure, it is only required for the power lines to be formed on the back side of the transistors. The “back side of the transistors” as used herein refers to the side, with respect to the transistors, opposite to the side on which the local interconnects, the metal interconnects, and the like connected to the transistors are stacked one upon another.

The power lines formed on the back side of the transistors may be formed in a plurality of interconnect layers.

### Other Configuration Example

The power lines on the back side of the transistors described above may also be formed using a semiconductor chip other than the semiconductor chip in which the transistors are formed.

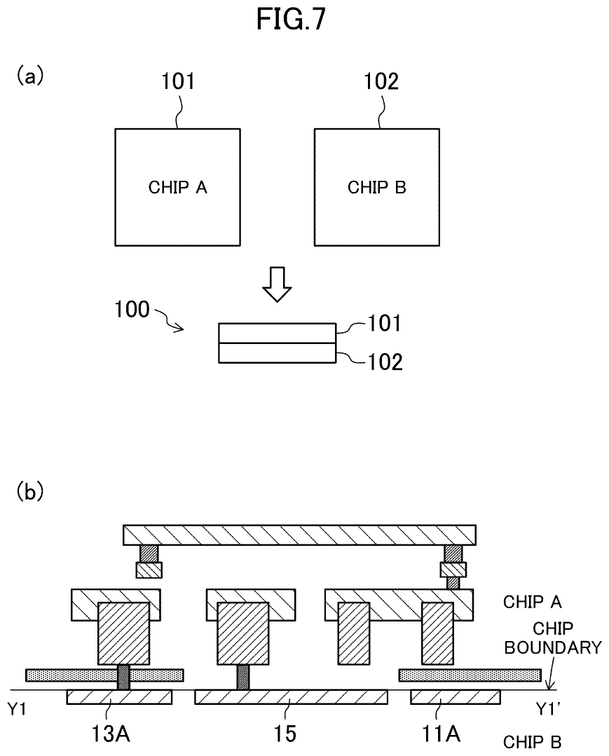

FIG. 7A shows another configuration example of the semiconductor integrated circuit device according to this embodiment. A semiconductor integrated circuit device 100 shown in FIG. 7A is constituted by a first semiconductor chip 101 (chip A) and a second semiconductor chip 102 (chip B) stacked one upon the other. In the chip A, the circuit block described above and the like are placed. In the chip B, power lines are formed in an interconnect layer provided on the surface. The chip B is bonded to the back of the chip A using bumps and the like.

FIG. 7B shows a cross section of this configuration example taken along line Y1-Y1′ in the double-height cell C3 of FIG. 4. As shown in FIG. 7B, the power lines 11A and 13A supplying VDD and the power line 15 supplying VSS are formed in the interconnect layer provided on the surface of the chip B. The power line 13A is connected to the active region 2P3 in the chip A through a via, and the power line 15 is connected to the active region 2N3 in the chip A through a via. The power lines 11 and 12 of the cell C1, the power lines 13 and 14 of the cell C2, and the power lines 12A, 14A, and 16 of the double-height cell C4 are also formed in the interconnect layer provided on the surface of the chip B.

Note that, in this configuration example, also, the power lines formed in the interconnect layer provided on the surface of the chip B may be formed in a plurality of interconnect layers.

### Other Layout Structure Examples

Other layout structure examples of the double-height cell C3 according to this embodiment will be described. Note that, in the following examples, the layout structure shown in FIGS. 4, 5A, and 5B is used as the basic configuration, and description may be omitted for configurations that can be easily known by analogy from the above description.

### (1) 2-Input AND Circuit

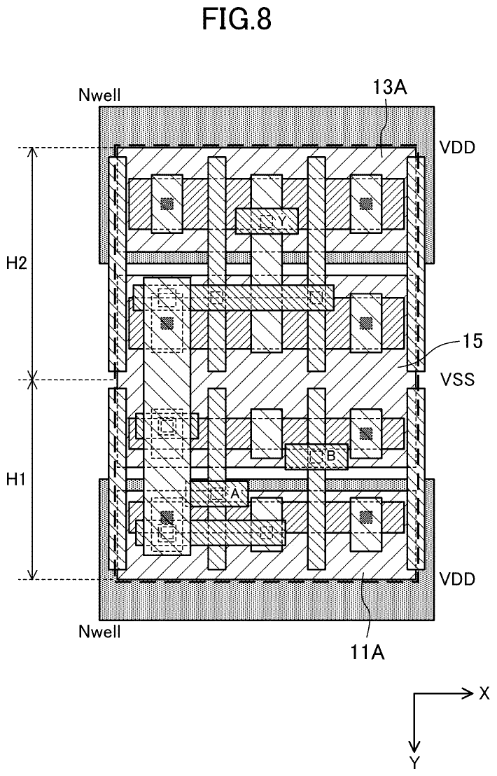

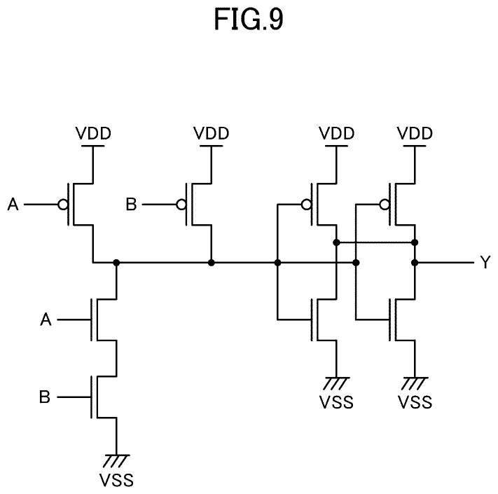

FIG. 8 is a plan view showing another layout structure of the double-height cell C3. The layout structure of FIG. 8 has a cell width 3/2 times that of FIG. 4. The cell C3 shown in FIG. 8 implements a 2-input AND circuit shown in FIG. 9. The 2-input AND circuit shown in FIG. 9 includes a NAND gate at the first stage and an inverter at the second stage. The second-stage inverter is constituted by two inverters connected in parallel. The first-stage NAND gate corresponds to the first logic circuit according to the present disclosure, and the second-stage inverter corresponds to the second logic circuit according to the present disclosure.

As shown in FIG. 8, in the cell C3, the power line 15 supplying VSS is laid in the center portion in the Y direction. Also, the power lines 13A and 11A supplying VDD are laid in the end portions in the Y direction. In the cell C3, in the upper-part region in the figure included in the cell row CR2, having the height H2, transistors constituting the second-stage inverter of the 2-input AND circuit are formed. In the lower-part region in the figure included in the cell row CR1, having the height H1, transistors constituting the first-stage NAND gate of the 2-input AND circuit are formed. In the double-height cell C3 of FIG. 8, the width of the nanosheets of the transistors constituting the second-stage inverter is greater than the width of the nanosheets of the transistors constituting the first-stage NAND gate. Therefore, the cell C3 can implement a 2-input AND circuit small in input capacity (equivalent to that of the cell C1) and high in output drive capability (equivalent to double that of the cell C2 because two inverters are connected in parallel) with a small area.

### (2) 2-Input OR Circuit

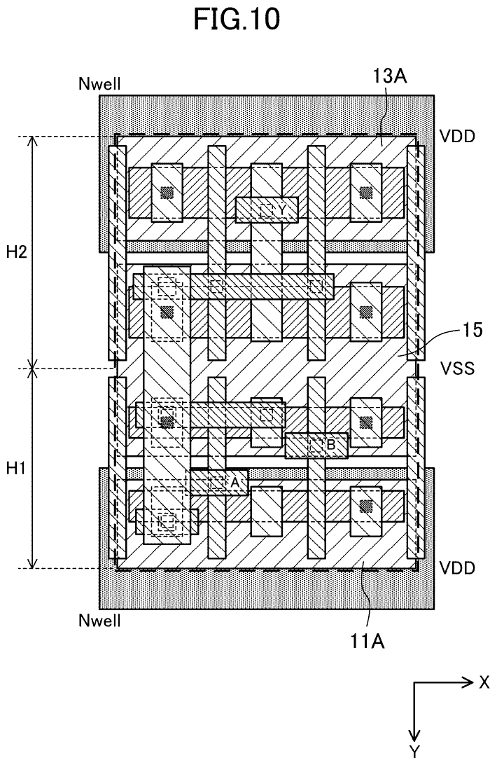

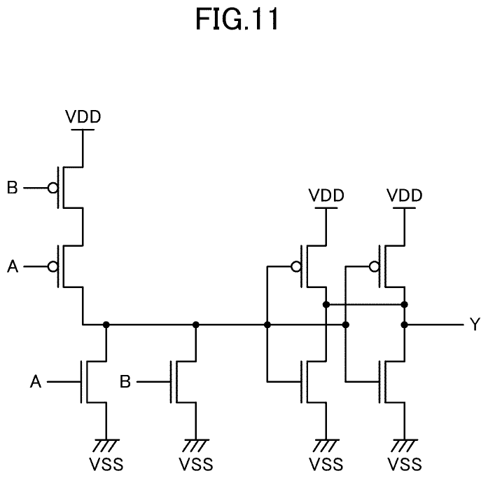

FIG. 10 is a plan view showing yet another layout structure of the double-height cell C3. The layout structure of FIG. 10 has a cell width 3/2 times that of FIG. 4. The cell C3 shown in FIG. 10 implements a 2-input OR circuit shown in FIG. 11. The 2-input OR circuit shown in FIG. 11 includes a NOR gate at the first stage and an inverter at the second stage. The second-stage inverter is constituted by two inverters connected in parallel. The first-stage NOR gate corresponds to the first logic circuit according to the present disclosure, and the second-stage inverter corresponds to the second logic circuit according to the present disclosure.

As shown in FIG. 10, in the cell C3, the power line 15 supplying VSS is laid in the center portion in the Y direction. Also, the power lines 13A and 11A supplying VDD are laid in the end portions in the Y direction. In the upper-part region in the figure included in the cell row CR2, having the height H2, transistors constituting the second-stage inverter of the 2-input OR circuit are formed. In the lower-part region in the figure included in the cell row CR1, having the height H1, transistors constituting the first-stage NOR gate of the 2-input OR circuit are formed.

In the double-height cell C3 of FIG. 10, the width of the nanosheets of the transistors constituting the second-stage inverter is greater than the width of the nanosheets of the transistors constituting the first-stage NOR gate. Therefore, the cell C3 can implement a 2-input OR circuit small in input capacity (equivalent to that of the cell C1) and high in output drive capability (equivalent to double that of the cell C2 because two inverters are connected in parallel) with a small area.

### (3) 4-Input AND Circuit

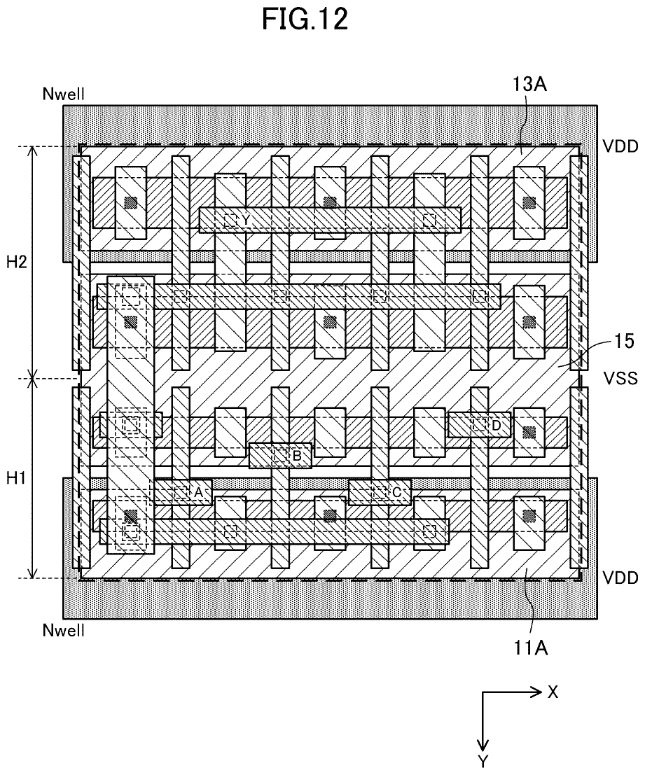

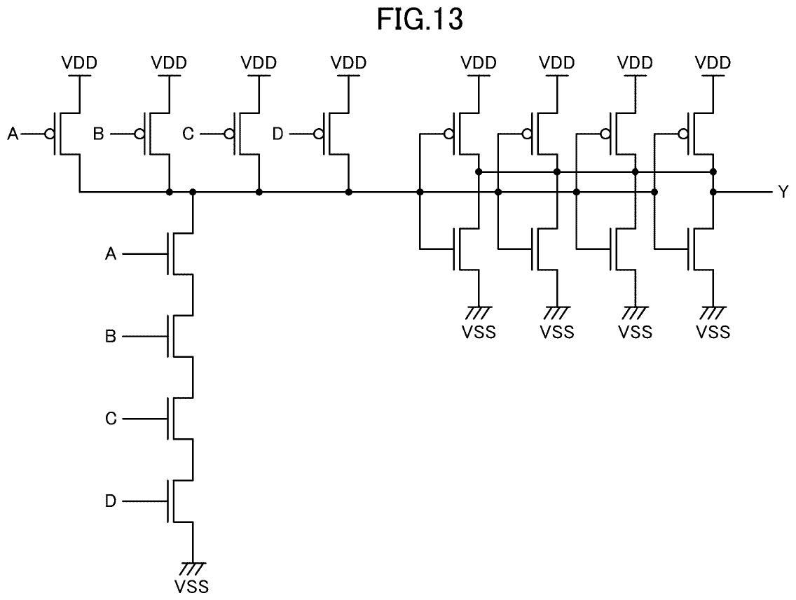

FIG. 12 is a plan view showing yet another layout structure of the double-height cell C3. The layout structure of FIG. 12 has a cell width 5/2 times that of FIG. 4. The cell C3 shown in FIG. 12 implements a 4-input AND circuit shown in FIG. 13. The 4-input AND circuit shown in FIG. 13 includes a 4-input NAND gate at the first stage and an inverter at the second stage. The second-stage inverter is constituted by four inverters connected in parallel. The first-stage 4-input NAND gate corresponds to the first logic circuit according to the present disclosure, and the second-stage inverter corresponds to the second logic circuit according to the present disclosure.

As shown in FIG. 12, in the cell C3, the power line 15 supplying VSS is laid in the center portion in the Y direction. Also, the power lines 13A and 11A supplying VDD are laid in the end portions in the Y direction. In the upper-part region in the figure included in the cell row CR2, having the height H2, transistors constituting the second-stage inverter of the 4-input AND circuit are formed. In the lower-part region in the figure included in the cell row CR1, having the height H1, transistors constituting the first-stage 4-input NAND gate of the 4-input AND circuit are formed.

In the double-height cell C3 of FIG. 12, the width of the nanosheets of the transistors constituting the second-stage inverter is greater than the width of the nanosheets of the transistors constituting the first-stage NAND gate. Therefore, the cell C3 can implement a 4-input AND circuit small in input capacity (equivalent to that of the cell C1) and high in output drive capability (equivalent to four times that of the cell C2 because four inverters are connected in parallel) with a small area.

### (4) Another 4-Input AND Circuit

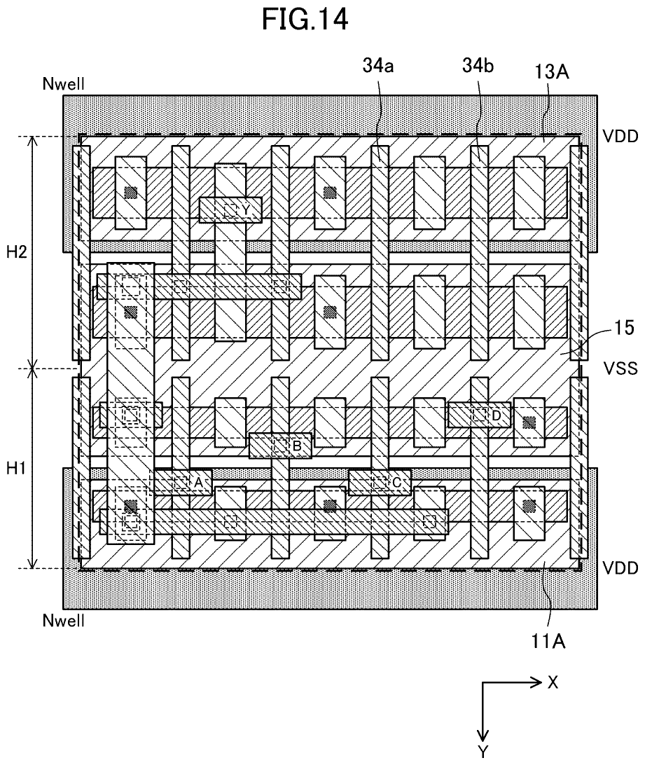

FIG. 14 is a plan view showing yet another layout structure of the double-height cell C3. The layout structure of FIG. 14 has a cell width 5/2 times that of FIG. 4. The cell C3 shown in FIG. 14 implements a 4-input AND circuit, like the layout structure of FIG. 12. In FIG. 14, however, the second-stage inverter is constituted by two inverters connected in parallel, not four inverters connected in parallel.

As shown in FIG. 14, in the cell C3, the power line 15 supplying VSS is laid in the center portion in the Y direction. Also, the power lines 13A and 11A supplying VDD are laid in the end portions in the Y direction. In the upper-part region in the figure included in the cell row CR2, having the height H2, transistors constituting the second-stage inverter of the 4-input AND circuit are formed. Note here that transistors constituted by gate interconnects 34a and 34b are dummy transistors that do not contribute to circuit operation. That is, the cell C3 of FIG. 14 includes dummy transistors. In the lower-part region in the figure included in the cell row CR1, having the height H1, transistors constituting the first-stage NAND gate of the 4-input AND circuit are formed.

In the double-height cell C3 of FIG. 14, the width of the nanosheets of the transistors constituting the second-stage inverter is greater than the width of the nanosheets of the transistors constituting the first-stage NAND gate. Therefore, the cell C3 can implement a 4-input AND circuit small in input capacity (equivalent to that of the cell C1) and high in output drive capability (equivalent to double that of the cell C2 because two inverters are connected in parallel) with a small area.

### Second Embodiment

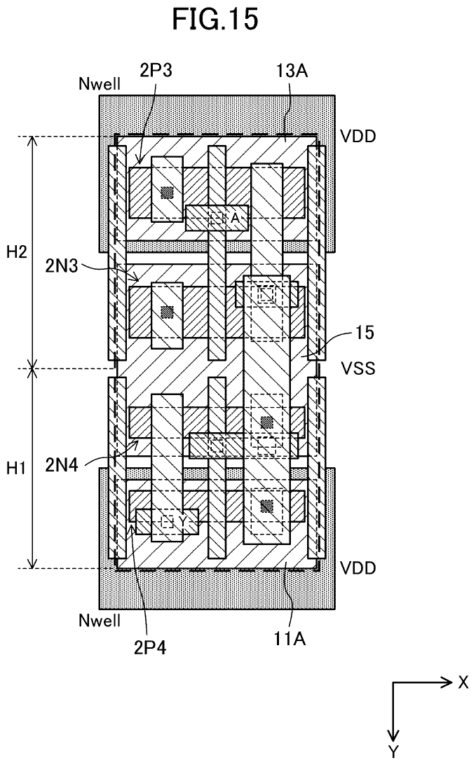

FIG. 15 is a plan view showing a layout structure example of the double-height cell C3 according to the second embodiment. The circuit structure of the cell C3 of FIG. 15 is as shown in FIG. 3, that is, constituted by two-staged inverters, forming a buffer circuit having an input A and an output Y.

In the layout structure of FIG. 15, in comparison with the layout structure of FIG. 4, the positions of the input-side inverter and the output-side inverter are changed with each other vertically in the figure. That is, in FIG. 15, transistors constituting the input-side inverter of the buffer circuit are formed in the upper-part region in the figure having the height H2 included in the cell row CR2. Transistors constituting the output-side inverter of the buffer circuit are formed in the lower-part region in the figure having the height H1 included in the cell row CR1. Note that, since the layout structure of FIG. 15 can be easily known by analogy from the description in the first embodiment, detailed description is omitted here.

In the double-height cell C3 shown in FIG. 15, the height H2 of the upper-part region in the figure included in the cell row CR2 is greater than the height H1 of the lower-part region in the figure included in the cell row CR1 (H2>H1). Therefore, the size of active regions 2P3 and 2N3 in the Y direction is greater than the size of active regions 2P4 and 2N4 in the Y direction. That is, the width of the nanosheets of transistors constituting the input-side inverter is greater than the width of the nanosheets of transistors constituting the output-side inverter. Therefore, in the cell C3, while the input capacity is great (equivalent to that of the cell C2), the output drive capability of the input-side inverter is great. Also, the input capacity of the output-side inverter is small. As a result, the delay inside the cell from the input-side inverter to the output-side inverter becomes small.

Therefore, when the output drive capability of a cell connected to the input A is sufficiently great and the load capacity due to a cell or cells and interconnects connected to the output Y is small, a small-area, high-speed semiconductor integrated circuit device can be implemented.

### Other Layout Structure Examples

Other layout structure examples of the double-height cell C3 according to this embodiment will be described. Note that description may be omitted for configurations that can be easily known by analogy from the above description.

### (1) 2-Input AND Circuit

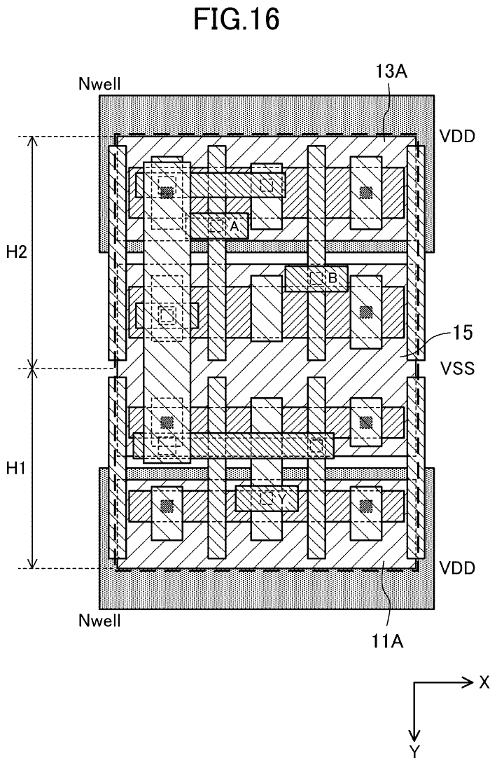

FIG. 16 is a plan view showing another layout structure of the double-height cell C3. The layout structure of FIG. 16 has a cell width 3/2 times that of FIG. 15. The cell C3 shown in FIG. 16 implements a 2-input AND circuit shown in FIG. 9.

In the layout structure of FIG. 16, in comparison with the layout structure of FIG. 8, the positions of the first-stage NAND gate and the second-stage inverter are changed with each other vertically in the figure. That is, transistors constituting the first-stage NAND gate of the 2-input AND circuit are formed in the upper-part region in the figure having the height H2 included in the cell row CR2. Transistors constituting the second-stage inverter of the 2-input AND circuit are formed in the lower-part region in the figure having the height H1 included in the cell row CR1.

In the double-height cell C3 of FIG. 16, the width of the nanosheets of transistors constituting the first-stage NAND gate is greater than the width of the nanosheets of transistors constituting the second-stage inverter. Therefore, in the cell C3, while the input capacity is great (equivalent to that of the cell C2), the output drive capability of the first-stage NAND gate is great. Also, the input capacity of the second-stage inverter is small. As a result, the delay inside the cell from the NAND gate to the inverter becomes small.

Therefore, when the output drive capabilities of cells connected to the inputs A and B are sufficiently great and the load capacity due to a cell or cells and interconnects connected to the output Y is small, a small-area, high-speed semiconductor integrated circuit device can be implemented.

### (2) 4-Input AND Circuit

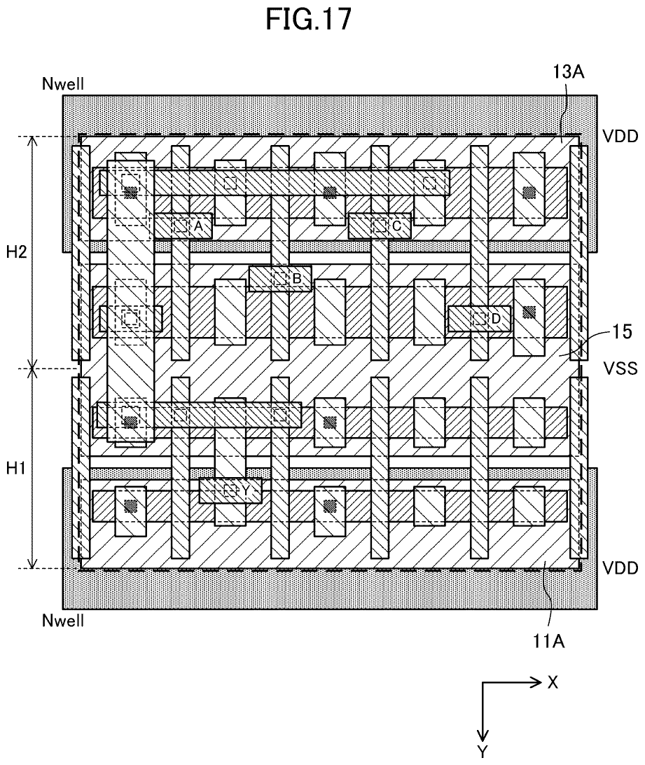

FIG. 17 is a plan view showing yet another layout structure of the double-height cell C3. The layout structure of FIG. 17 has a cell width 5/2 times that of FIG. 15. The cell C3 shown in FIG. 17 implements a 4-input AND circuit same in layout structure as that of FIG. 14.

In the layout structure of FIG. 17, in comparison with the layout structure of FIG. 14, the positions of the first-stage 4-input NAND gate and the second-stage inverter are changed with each other vertically in the figure. That is, transistors constituting the first-stage 4-input NAND gate of the 4-input AND circuit are formed in the upper-part region in the figure having the height H2 included in the cell row CR2. Transistors constituting the second-stage inverter of the 4-input AND circuit are formed in the lower-part region in the figure having the height H1 included in the cell row CR1.

In the double-height cell C3 of FIG. 17, the width of the nanosheets of transistors constituting the first-stage 4-input NAND gate is greater than the width of the nanosheets of transistors constituting the second-stage inverter. Therefore, in the cell C3, while the input capacity is great (equivalent to that of the cell C2), the output drive capability of the first-stage 4-input NAND gate is great. Also, the input capacity of the second-stage inverter is small. As a result, the delay inside the cell from the NAND gate to the inverter becomes small.

Therefore, when the output drive capabilities of cells connected to the inputs A, B, C, and D are sufficiently great and the load capacity due to a cell or cells and interconnects connected to the output Y is small, a small-area, high-speed semiconductor integrated circuit device can be implemented.

While the nanosheets have the structure of three sheets lying one above another and the cross-sectional shape of the sheet structure is illustrated as a rectangle in the above embodiments, the number of sheets, and the cross-sectional shape, of the structure of the nanosheets are not limited to these.

According to the present disclosure, the performance of a standard cell lying astride a plurality of standard cell rows different in height can be improved. The present disclosure is therefore useful for reducing the area, and increasing the speed, of a semiconductor integrated circuit device, for example.

1. A semiconductor integrated circuit device, comprising:
a first cell row including a plurality of standard cells arranged in a first direction;
a second cell row including a plurality of standard cells arranged in the first direction and adjoining the first cell row in a second direction perpendicular to the first direction; and
a double-height cell placed astride the first cell row and the second cell row and having a height greater than the height of the plurality of standard cells included in the first and second cell rows,
wherein
the height of the second cell row is greater than the height of the first cell row,
the double-height cell includes
a first logic circuit configured to receive an input signal from an input terminal and output a signal to an internal node, and
a second logic circuit configured to receive the signal from the internal node and output an output signal to an output terminal,
a first transistor constituting the first logic circuit is formed in a region included in the first cell row, and
a second transistor constituting the second logic circuit is formed in a region included in the second cell row.

2. The semiconductor integrated circuit device of claim 1, wherein
the first and second transistors are nanosheet field effect transistors (FETs), and
the width of a nanosheet of the second transistor is greater than the width of a nanosheet of the first transistor.

3. The semiconductor integrated circuit device of claim 1, wherein
the first cell row includes
a first power line formed on a back side of the first transistor, extending in the first direction, and supplying a first power supply voltage, and
the second cell row includes
a second power line formed in a same interconnect layer as the first power line, extending in the first direction, and supplying the first power supply voltage.

4. The semiconductor integrated circuit device of claim 3, wherein
the second power line is greater in width in the second direction than the first power line.

5. The semiconductor integrated circuit device of claim 3, wherein
the first and second power lines are formed in an interconnect layer provided in a first semiconductor chip in which the first and second transistors are formed.

6. The semiconductor integrated circuit device of claim 3, wherein
the first and second power lines are formed in an interconnect layer provided in a second semiconductor chip bonded to a back of a first semiconductor chip in which the first and second transistors are formed.

7. The semiconductor integrated circuit device of claim 1, wherein
the double-height cell includes
a dummy transistor that does not contribute to a logical function of a circuit.

8. A semiconductor integrated circuit device, comprising:
a first cell row including a plurality of standard cells arranged in a first direction;
a second cell row including a plurality of standard cells arranged in the first direction and adjoining the first cell row in a second direction perpendicular to the first direction; and
a double-height cell placed astride the first cell row and the second cell row and having a height greater than the height of the plurality of standard cells included in the first and second cell rows,
wherein
the height of the second cell row is greater than the height of the first cell row,
the double-height cell includes
a first logic circuit configured to receive an input signal from an input terminal and output a signal to an internal node, and
a second logic circuit configured to receive the signal from the internal node and output an output signal to an output terminal,
a first transistor constituting the first logic circuit is formed in a region included in the second cell row, and
a second transistor constituting the second logic circuit is formed in a region included in the first cell row.

9. The semiconductor integrated circuit device of claim 8, wherein
the first and second transistors are nanosheet field effect transistors (FETs), and
the width of a nanosheet of the second transistor is smaller than the width of a nanosheet of the first transistor.

10. The semiconductor integrated circuit device of claim 8, wherein
the first cell row includes
a first power line formed on a back side of the first transistor, extending in the first direction, and supplying a first power supply voltage, and
the second cell row includes
a second power line formed in a same interconnect layer as the first power line, extending in the first direction, and supplying the first power supply voltage.

11. The semiconductor integrated circuit device of claim 10, wherein
the second power line is greater in width in the second direction than the first power line.

12. The semiconductor integrated circuit device of claim 10, wherein
the first and second power lines are formed in an interconnect layer provided in a first semiconductor chip in which the first and second transistors are formed.

13. The semiconductor integrated circuit device of claim 10, wherein
the first and second power lines are formed in an interconnect layer provided in a second semiconductor chip bonded to a back of a first semiconductor chip in which the first and second transistors are formed.

14. The semiconductor integrated circuit device of claim 8, wherein
the double-height cell includes
a dummy transistor that does not contribute to a logical function of a circuit.
